(19) United States
(12) Patent Application Publication
(10) Pub. No.: US 2026/0319023 A1
(43) Pub. Date: Oct. 15, 2026

(54) METHOD FOR DETECTING CONNECTION FAILURE OF BATTERY MODULE, AND APPARATUS FOR DIAGNOSING BATTERY MODULE

(71) Applicant: MONA INC., Jeollabuk-do (KR)

(72) Inventors: Yong Jun CHOI, Gyeonggi-do (KR); Soon Jong YU, Gyeonggi-do (KR); Yong Gi YOO, Gyeonggi-do (KR)

(73) Assignee: MONA INC., Jeollabuk-do (KR)

(21) Appl. No.: 19/485,659

(22) PCT Filed: Jul. 30, 2024
(86) PCT No.: PCT/KR2024/011174

§ 371 Date: Nov. 18, 2025

(30) Foreign Application Priority Data
Oct. 31, 2023 (KR) 10-2023-0148426

(51) Int. Cl. G01R 31/66; G01R 31/367; G01R 31/389; G01R 31/396

(52) U.S. Cl. CPC G01R 31/66; G01R 31/367; G01R 31/389; G01R 31/396

(57) ABSTRACT

Disclosed are a method of identifying a connection failure in a battery module, and a battery module diagnostic apparatus. The battery module diagnostic apparatus measures a first impedance of the battery module, calculates a second impedance by measuring impedances of the plurality of cell modules, respectively, and summing the measured impedances, and determines whether a connection failure exists in the battery module, based on a difference between the first impedance and the second impedance. This application was supported by the Regulation-Free Special Zone project of the Ministry of SMEs and Startups of the Republic of Korea (Project No.: P0023243, Project Identification No.: 1425182671, Managed by: Korea Institute for Advancement of Technology, Project Title: Demonstration of Driving Stability of Converted Electric Vehicles).

### TECHNICAL FIELD

The present disclosure relates to a method of identifying a connection failure in a battery module, and a battery module diagnostic apparatus, and more particularly, to a method and an apparatus for identifying a connection failure between cell modules constituting a battery module, the connection failure being caused by various factors such as a welding failure.

This application was supported by the Regulation-Free Special Zone project of the Ministry of SMEs and Startups of the Republic of Korea (Project No.: P0023243, Project Identification No.: 1425182671, Managed by: Korea Institute for Advancement of Technology, Project Title: Demonstration of Driving Stability of Converted Electric Vehicles).

### BACKGROUND ART

Electrochemical impedance spectroscopy (EIS) is a method that analyzes frequency-dependent resistance characteristics by applying alternating current electrical signals of various frequencies to a battery and measuring responses to the signals. The time required to analyze the resistance characteristics is inversely proportional to the magnitude of frequency, and in particular, analyzing the resistance characteristics at low frequencies below several Hz is time-consuming.

Another battery inspection method is the alternating current internal resistance (AC-IR) measurement method. AC-IR measurement typically measures a battery's response to a 1-kHz alternating current signal without changing the frequency.

The electrical capacity of battery systems continues to increase as battery applications expand from small devices to electric vehicles, and consequently, individual battery cells have been designed with lower internal resistance and higher energy capacity. As battery design approaches evolve and diversify, the conventional AC-IR measurement method, which measures at 1 kHz, faces challenges in accurately characterizing large-capacity batteries, and impedance spectroscopy struggles to meet battery measurement demands due to its lengthy inspection time.

Defects in battery modules including a plurality of cells are broadly categorized into two types: defects within the cells themselves; and defects in the electrical connections between the cells. While conventional impedance spectroscopy or AC-IR measurement methods may identify defects in the cells themselves, they have limitations in detecting connection defects between the cells.

### SUMMARY OF INVENTION

### Technical Problem

An objective of an embodiment of the present disclosure is to provide a method and apparatus for readily identifying a connection failure in a battery module that includes a plurality of cell modules, wherein the connection failure is caused by various factors such as a welding failure.

### Solution to Problem

To achieve the above objective, an example of a method of identifying a connection failure in a battery module in which a plurality of cell modules are connected in series, according to an embodiment of the present disclosure, includes: measuring a first impedance of the battery module; calculating a second impedance by measuring impedances of the plurality of cell modules, respectively, and summing the measured impedances; and determining whether a connection failure exists in the battery module, based on a difference between the first impedance and the second impedance.

To achieve the above objective, an example of a battery module diagnostic apparatus according to an embodiment of the present disclosure includes: a first measurement unit configured to determine a first impedance of a battery module in which a plurality of cell modules are connected in series; a second measurement unit configured to determine a second impedance by measuring impedances of the plurality of cell modules, respectively, and summing the measured impedances; and a diagnosis unit configured to determine whether a connection failure exists in the battery module, based on a difference between the first impedance and the second impedance.

### Advantageous Effects of Invention

According to an embodiment of the present disclosure, a connection failure between cell modules within a battery module may be identified quickly and accurately. Because impedance measurements of the individual cell modules and the entire battery module are used to identify a connection failure, the measured impedance values may be utilized to determine the state of the battery module or the cell modules (e.g., a state of health (SOH) or a state of charge (SOC)).

### BRIEF DESCRIPTION OF DRAWINGS

FIG. 1 is a diagram illustrating an example of a battery module diagnostic apparatus according to an embodiment of the present disclosure,

FIG. 2 is a diagram illustrating an example of battery modules according to an embodiment of the present disclosure,

FIG. 3 is a diagram illustrating an example of a method of measuring an impedance of a battery module, according to an embodiment of the present disclosure,

FIG. 4 is a flowchart illustrating an embodiment of a method of identifying a connection failure in a battery module, according to an embodiment of the present disclosure,

FIG. 5 is a diagram illustrating an example of a method of determining frequency-specific impedances, according to an embodiment of the present disclosure,

FIG. 6 is a graph showing impedance measurements of a battery module with a connection failure,

FIG. 7 is a graph showing impedance measurements of a normal battery module,

FIG. 8 is a graph showing some of the impedance measurements from FIGS. 6 and 7 together,

FIG. 9 is a graph showing battery module impedances and sums of cell module impedances for a normal battery module,

FIG. 10 is a graph showing battery module impedances and sums of cell module impedances for a battery module with a connection failure,

FIG. 11 is a graph showing a distribution of difference values between frequency-specific battery module impedances and sums of frequency-specific cell module impedances, according to an embodiment of the present disclosure,

FIG. 12 is a diagram illustrating a regression analysis graph for a distribution of impedance difference values of a normal battery module,

FIG. 13 is a diagram illustrating a regression analysis graph for a distribution of impedance difference values of a battery module with a connection failure, and

FIG. 14 is a diagram illustrating a configuration of an example of a battery module diagnostic apparatus according to an embodiment of the present disclosure.

### MODE FOR THE INVENTION

Hereinafter, a method of identifying a connection failure in a battery module and a battery module diagnostic apparatus according to an embodiment of the present disclosure will be described in detail with reference to the accompanying drawings.

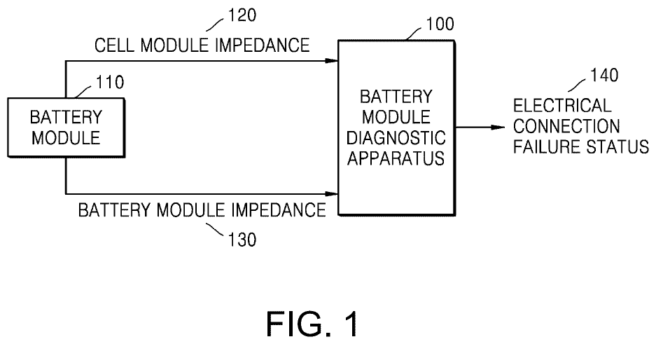

FIG. 1 is a diagram illustrating an example of a battery module diagnostic apparatus according to an embodiment of the present disclosure.

Referring to FIG. 1, in response to receiving an impedance measured by applying a frequency to a battery module 110, a battery module diagnostic apparatus 100 (hereinafter referred to as the ‘diagnostic apparatus’) analyzes the impedance to determine an electrical connection failure 140 in the battery module 110, and outputs a result of the determination. The electrical connection failure 140 may be caused by various factors, such as a welding failure between cell modules.

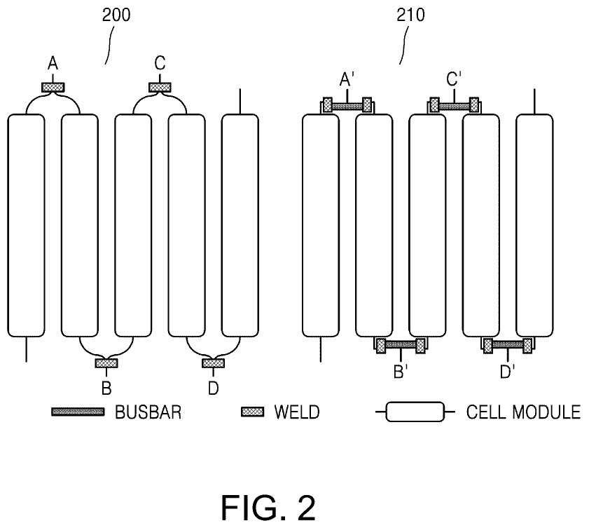

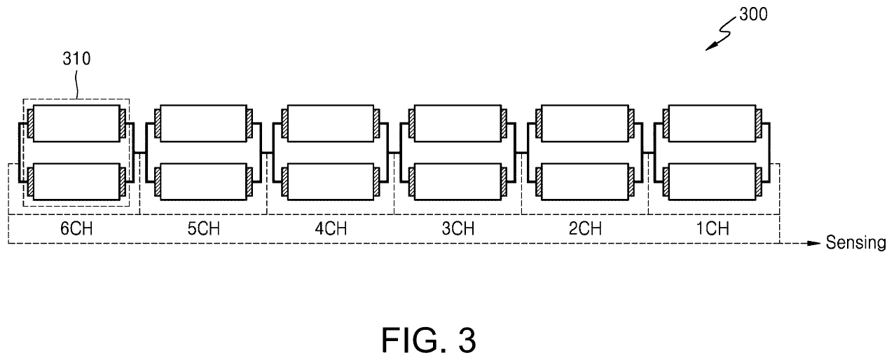

The battery module 110 includes a plurality of cell modules. A cell module includes one or more battery cells connected in series and/or in parallel. An example of a cell module in which two battery cells are connected in parallel is illustrated in FIG. 3. A plurality of cell modules may be connected in series or in parallel to constitute the battery module 110. Connections between the plurality of cell modules may be established through various methods, such as welding or using busbars. An example of the battery module 110 in which a plurality of cell modules are connected to each other through a method such as welding is illustrated in FIG. 2.

An impedance of each cell module (i.e., a cell module impedance 120) and an impedance of the entire battery module (i.e., a battery module impedance 130) may be measured by applying an alternating current signal of a certain frequency to the battery module 110 and to each of the plurality of cell modules within the battery module, respectively. An example of a method of measuring the cell module impedance 120 and the battery module impedance 130 will be further described with reference to FIG. 3.

FIG. 2 is a diagram illustrating an example of battery modules according to an embodiment of the present disclosure.

Referring to FIG. 2, battery modules 200 and 210 each include a plurality of cell modules. The present embodiment illustrates the battery module 200 in which a plurality of cell modules are connected to each other by welds A, B, C, and D, and the battery module 210 in which a plurality of cell modules are connected to each other by using busbars A′, B′, C′, and D′. A connection failure in the battery modules 200 and 210 may be a connection defect between the cell modules, such as a defect in a weld or a busbar connection. Electrical connection defects may occur in a battery module for various other reasons. The present embodiment is provided only as an example to aid in understanding, and connections between the cell modules may be implemented in various ways and are not limited to the present embodiment.

FIG. 3 is a diagram illustrating an example of a method of measuring an impedance of a battery module, according to an embodiment of the present disclosure.

Referring to FIG. 3, a battery module 300 includes a plurality of cell modules 310 connected in series. In the present embodiment, the cell module 310 includes two battery cells connected in parallel. The battery module 300 in the present embodiment is provided only as an example to aid in understanding, and may be modified in various ways according to other embodiments.

The diagnostic apparatus 100 measures an overall impedance of the battery module 300 and an impedance of each cell module 310 constituting the battery module. The diagnostic apparatus 100 may measure an impedance of the battery module 300 by connecting probes to two terminals (e.g., a positive terminal and a negative terminal) of the battery module 300, respectively, and applying a predefined measurement frequency. In another embodiment, the diagnostic apparatus 100 may measure frequency-specific impedances by applying a plurality of different measurement frequencies to the battery module 300, respectively. A range of measurement frequencies for the impedance measurement may be modified in various ways according to embodiments. For example, frequencies used in electrochemical impedance spectroscopy may be used as the measurement frequencies in the present embodiment.

The diagnostic apparatus 100 measures an impedance of each cell module 310 that constitutes the battery module 300, by applying a measurement frequency to the cell module. For example, in the case of FIG. 2, the diagnostic apparatus 100 may measure an impedance of each cell module by connecting probes to the positive electrode and the negative electrode of the cell module (e.g., in FIG. 2, to A and B, to B and C, or to C and D) and applying a measurement frequency. The measurement frequencies used to measure the impedances of the cell modules may be identical to the measurement frequencies used to measure the impedance of the battery module 300. For example, when three different measurement frequencies F1, F2, and F3 are used to measure the impedance of the battery module 300, the same three different measurement frequencies F1, F2, and F3 may also be used to measure the impedance of each cell module.

In an embodiment, the diagnostic apparatus 100 may connect probes to the positive electrode and the negative electrode of the battery module 300, and connect probes to the positive electrode and the negative electrode of each cell module 310. The diagnostic apparatus 100 may simultaneously measure the impedance of the battery module 300 and the impedance of each cell module 310 by applying one or more measurement frequencies. The present embodiment illustrates an example in which the diagnostic apparatus 100 includes six sensing channels for simultaneously measuring impedances of six cell modules 310. In another embodiment, the diagnostic apparatus 100 may also measure a battery module impedance and each cell module impedance separately.

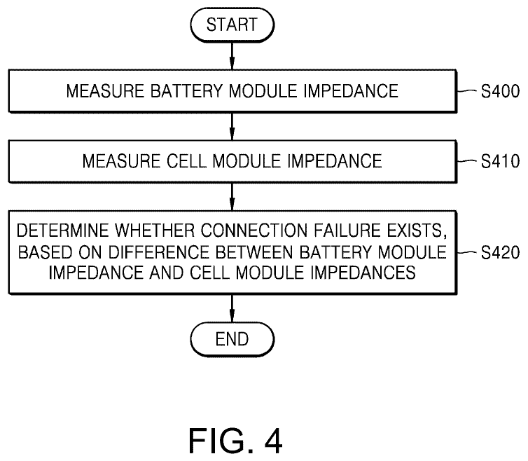

FIG. 4 is a flowchart illustrating an embodiment of a method of identifying a connection failure in a battery module, according to an embodiment of the present disclosure.

Referring to FIGS. 1 and 4, the diagnostic apparatus 100 measures a first impedance of the battery module 110 (i.e., the battery module impedance 130) (operation S400). For example, the diagnostic apparatus 100 may measure the first impedance by applying an alternating current signal of at least one predefined measurement frequency to the battery module 110.

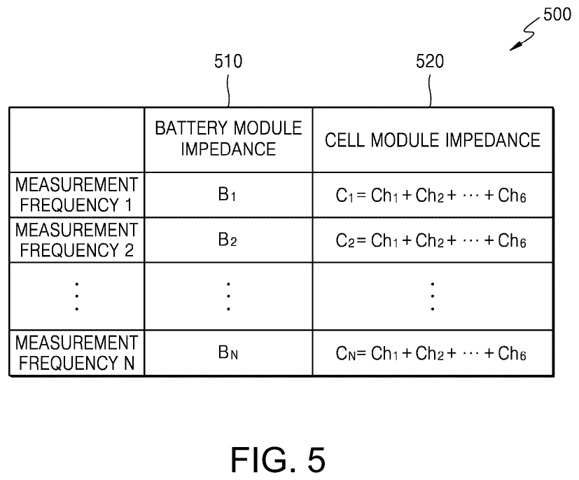

The diagnostic apparatus 100 calculates a second impedance by measuring impedances of the plurality of cell modules connected in series within the battery module 110 (i.e., cell module impedances) and summing the measured impedances (operation S410). For example, the diagnostic apparatus 100 measures an impedance of each cell module by applying an alternating current signal of at least one predefined measurement frequency, and then calculates the second impedance by summing all of the impedances of the respective cell modules. An example of calculating frequency-specific second impedances is illustrated in FIG. 5.

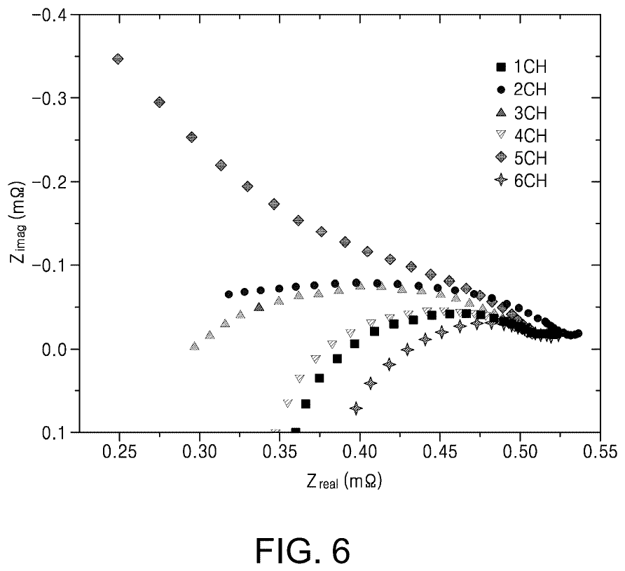

The diagnostic apparatus 100 determines whether an electrical connection failure exists in the battery module 110, based on a difference between the first impedance (the battery module impedance) and the second impedance (the sum of the cell module impedances) (operation S320). In an embodiment, when a difference between a frequency-specific first impedance and a frequency-specific second impedance deviates from a predefined reference value, the diagnostic apparatus 100 may determine that a connection failure exists. Alternatively, the diagnostic apparatus 100 may determine whether a connection failure exists, through a statistical analysis or a regression analysis on a difference between a frequency-specific first impedance and a frequency-specific second impedance. Various methods of determining whether a failure exists will be described below with reference to FIG. 6 and the subsequent drawings.

FIG. 5 is a diagram illustrating an example of a method of determining frequency-specific impedances, according to an embodiment of the present disclosure.

Referring to FIG. 5, the diagnostic apparatus 100 may measure frequency-specific battery module impedances 510 by applying a plurality of predefined measurement frequencies to a battery module (500). Furthermore, the diagnostic apparatus may measure frequency-specific cell module impedances 520 by applying a plurality of predefined measurement frequencies to each cell module.

For example, the diagnostic apparatus 100 may measure an impedance of each cell module within the battery module by applying a first measurement frequency to the cell module. As in the example of FIG. 3, in a case in which the battery module 300 includes six cell modules the diagnostic apparatus 100 may measure six impedances Ch1, Ch2, Ch3, Ch4, Ch5, and Ch6 corresponding to the six cell modules 310 via six channels. The diagnostic apparatus 100 calculates a second impedance C1 for the first measurement frequency by summing the impedances of the six cell modules (Ch1+Ch2+Ch3+Ch4+Ch5+Ch6). Furthermore, the diagnostic apparatus 100 calculates a second impedance C2 for a second measurement frequency by applying the second measurement frequency to each cell module to obtain impedance values via the six channels, and summing the obtained values. In this manner, the diagnostic apparatus 100 may obtain frequency-specific second impedances C1, C2, . . . , CN, from the first measurement frequency to the N-th measurement frequency.

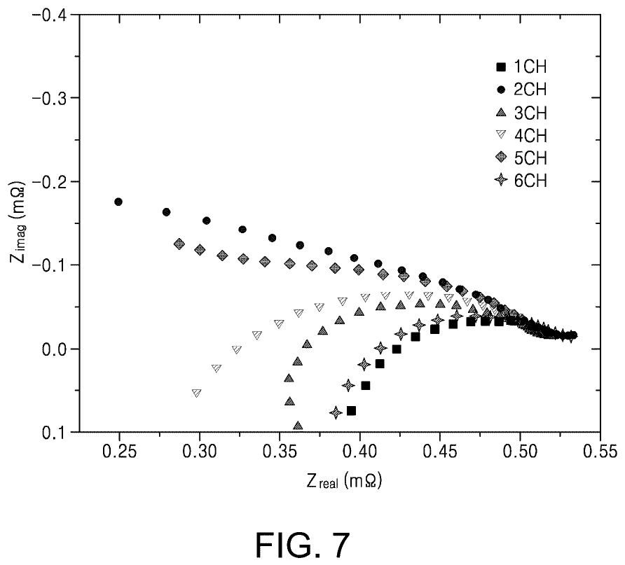

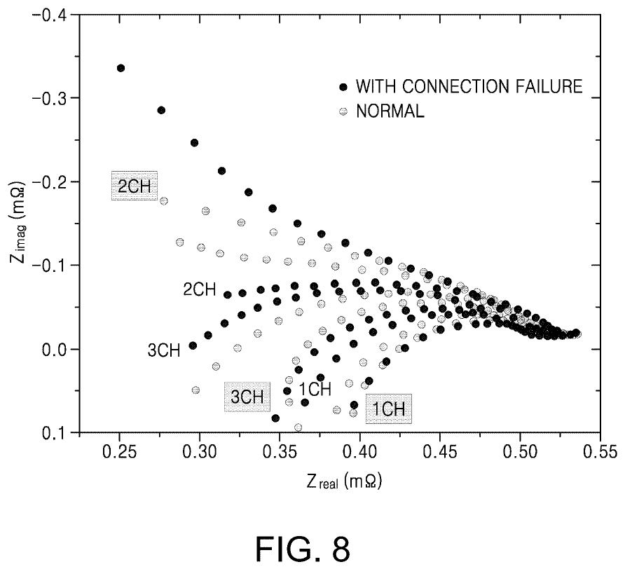

FIG. 6 is a graph showing impedance measurements of a battery module with a connection failure, and FIG. 7 is a graph showing impedance measurements of a normal battery module. FIG. 8 is a graph showing some of the impedance measurements from FIGS. 6 and 7 together.

FIGS. 6 to 8 show frequency-specific cell module impedance measurements of a battery module that includes six cell modules as in FIG. 3. Ch1, Ch2, . . . , Ch6 denote the impedance measurements of the respective cell modules. Referring to FIG. 8, it may be seen that there is a difference between the cell module impedances of the battery module in a normal state (FIG. 7) and the cell module impedances of the battery module with a connection failure (FIG. 6). The present embodiment is provided only as an example to show that there is a difference in the cell module impedance between a normal battery module and a battery module with a connection failure, and the present disclosure is not limited to the present embodiment. Furthermore, the measurement frequency range may vary according to the embodiment, and when the type of battery module or the measurement frequency range is changed, the shape of the graphs in FIGS. 6 to 8 may also change.

In an embodiment, the diagnostic apparatus 100 may determine whether a connection failure exists in a target battery module, by measuring cell module impedances of the target battery module, and then comparing the measured impedances with previously measured cell module impedances of the battery module in a normal state. In this case, to determine whether a connection failure exists in the battery module, cell module impedance values of a normal battery module need to be known in advance.

For example, a user may first inspect a battery module for connection failures by using various related-art inspection methods, such as visual inspection or other equipment-based inspection, and when the connection state is determined to be normal, measure and store cell module impedances of the battery module as cell module impedances of a normal battery module as in FIG. 7. Subsequently, a failure in the same battery module may be determined by measuring its cell module impedances and comparing the measured cell module impedances with the previously stored cell module impedances in the normal state.

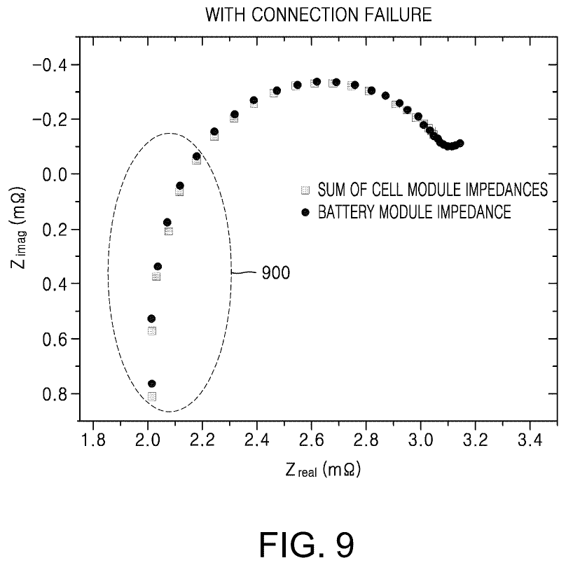

In another embodiment, a connection failure in a battery module may be determined without a prior measurement of impedances of a normal battery module as in FIG. 7, and this method will be described below with reference to FIG. 9 and the subsequent drawings.

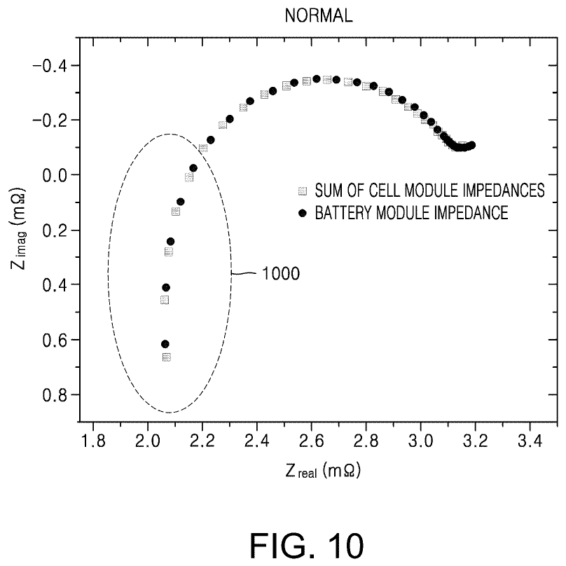

FIG. 9 is a graph showing battery module impedances and sums of cell module impedances for a battery module with a connection failure, and FIG. 10 is a graph showing battery module impedances and sums of cell module impedances for a normal battery module.

Referring to FIGS. 9 and 10, for the battery module with a connection failure, there are differences (A) between frequency-specific battery module impedances (i.e., frequency-specific first impedances) and the sums of frequency-specific cell module impedances (i.e., frequency-specific second impedances). In addition, for the normal battery module, there are differences (B) between frequency-specific battery module impedances (i.e., frequency-specific first impedances) and sums of frequency-specific cell module impedances (i.e., frequency-specific second impedances).

It may be seen that the pattern of the impedance differences (A) of the battery module with a connection failure is different from the pattern of the impedance differences (B) of the normal battery module. By utilizing these characteristics, when a difference between a frequency-specific first impedance and a frequency-specific second impedance deviates from a predefined reference value, the diagnostic apparatus 100 may determine that a connection failure exists. For example, in the case of FIG. 5, the diagnostic apparatus 100 may obtain a difference (B1−C1) between the first impedance and the second impedance for a first measurement frequency, and obtain a difference ‘B2−C2’ for the second measurement frequency. In this manner, the diagnostic apparatus 100 may obtain differences between the first impedances and the second impedances for the measurement frequencies from the first measurement frequency to the N-th measurement frequency. The diagnostic apparatus 100 may determine whether a connection failure exists by performing a statistical analysis (e.g., calculating a mean, a variance, a maximum difference, a minimum difference, or the like) on the obtained difference values for the respective measurement frequencies, and comparing a result of the analysis with a predetermined reference value. For example, when an average of the difference values for the respective measurement frequencies deviates from a predefined reference value, the diagnostic apparatus 100 may determine that a connection failure exists. The reference value may be determined in advance through various methods, such as experimentation, and stored in the diagnostic apparatus 100.

In another embodiment, the diagnostic apparatus 100 may determine whether a connection failure exists by using only the differences between the first impedances and the second impedances within a partial frequency range rather than the entire range of measurement frequencies. Referring again to FIGS. 9 and 10, the degrees of change in certain intervals 900 and 1000 on the Nyquist plots, where the imaginary value shows significant variation relative to the same real value, may be used to determine a connection failure. For example, the intervals 900 and 1000 within the frequency range to be used for determining a connection failure may be determined by designating a certain range (e.g., 2.0 to 2.2) on the real axis (Zreal).

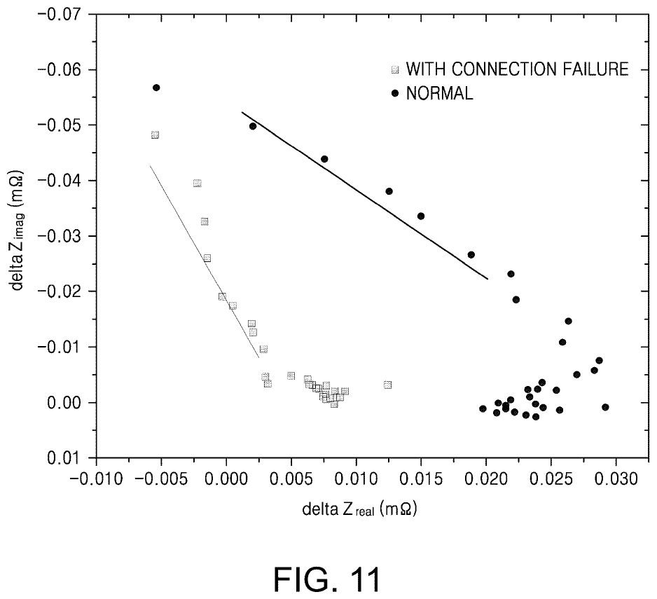

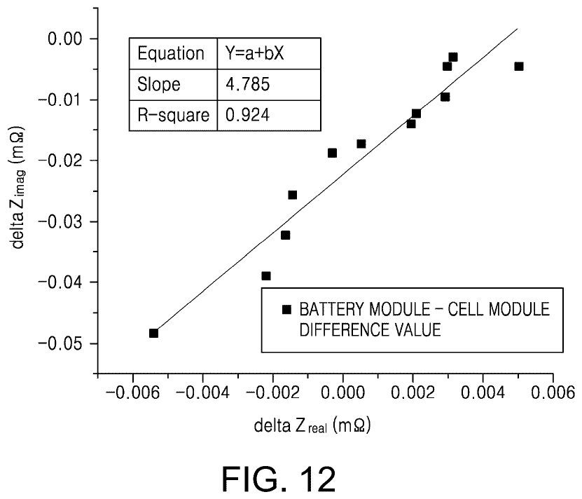

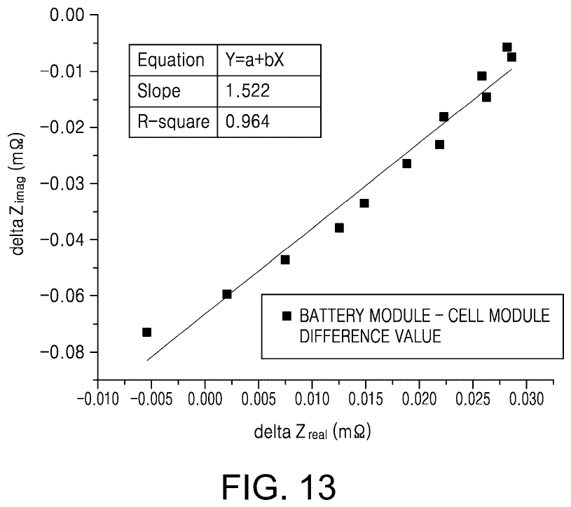

FIG. 11 is a graph showing a distribution of difference values between frequency-specific battery module impedances and sums of frequency-specific cell module impedances, according to an embodiment of the present disclosure. FIG. 12 is a diagram illustrating a regression analysis graph for a distribution of impedance difference values of a normal battery module, and FIG. 13 is a diagram illustrating a regression analysis graph for a distribution of impedance difference values of a battery module with a connection failure.

Referring to FIG. 11, it may be seen that the distribution of impedance difference values (=first impedance−second impedance) for the normal battery module is different from the distribution of impedance difference values (=first impedance−second impedance) for the battery module with a connection failure. Thus, when the distribution of impedance difference values of the battery module deviates from a predefined reference value, the diagnostic apparatus 100 may determine that a connection failure exists.

Referring to FIGS. 12 and 13, by performing a linear regression analysis on the distribution of difference values between frequency-specific first impedances and frequency-specific second impedances, the diagnostic apparatus 100 may obtain a linear graph representing the distribution of difference values. FIGS. 12 and 13 show results of a linear regression analysis on the distribution of difference values of the frequency impedances in the partial regions 900 and 1000 of FIGS. 9 and 10, respectively.

When the slope of the linear graph is less than or equal to a predefined reference value (e.g., 2.0), or when the coefficient of determination (R-Square) of the linear graph is greater than or equal to a predefined reference value (e.g., 0.95), the diagnostic apparatus 100 may determine that a connection failure exists. The reference value for determining a connection failure may be determined in advance through various experiments or the like. For example, after determining distributions of impedance difference values and regression analysis values for a plurality of normal battery modules through experiments, a reference value for a normal range may be predefined and used.

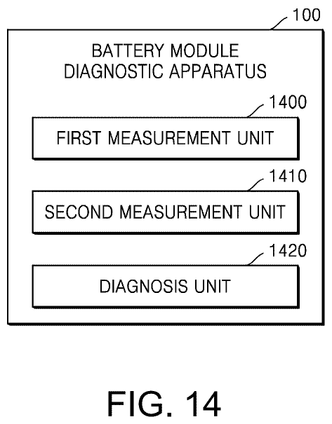

FIG. 14 is a diagram illustrating a configuration of an example of a battery module diagnostic apparatus according to an embodiment of the present disclosure.

Referring to FIG. 14, the battery module diagnostic apparatus 100 includes a first measurement unit 1400, a second measurement unit 1410, and a diagnosis unit 1420. In an embodiment, the battery module diagnostic apparatus 100 may be a type of computing device that receives and processes impedance values measured by the method of FIG. 3, and may include a memory, a processor, and an input/output device. In another embodiment, the battery module diagnostic apparatus 100 may be an apparatus that includes a measurement module configured to apply a frequency and measure an impedance, in order to measure a battery module impedance and cell module impedances by using the measurement method of FIG. 3. The following description assumes that the battery module diagnostic apparatus includes a module configured to directly measure an impedance.

The first measurement unit 1400 determines a first impedance (a battery module impedance) of a battery module in which a plurality of cell modules are connected in series. In a case in which a separate measurement module is provided, the first measurement unit 1400 may receive battery module impedance measurements from the separate measurement module. In a case in which a measurement module is included in the first measurement unit 1400, the first measurement unit 1400 may directly measure an impedance of the battery module by applying at least one measurement frequency to the battery module.

The second measurement unit 1410 calculates a second impedance by measuring a cell module impedance for each of the plurality of cell modules and summing the measured cell module impedances. In a case in which a separate measurement module is provided, the second measurement unit 1410 may receive cell module impedances from the separate measurement module. In a case in which a measurement module is included in the second measurement unit 1410, the second measurement unit 1410 may directly determine a cell module impedance by applying at least one measurement frequency to each cell module.

The diagnosis unit 1420 determines whether a connection failure exists in the battery module, based on a difference between the first impedance and the second impedance. In an embodiment, the diagnosis unit 1420 may obtain a linear graph by performing a regression analysis on difference values between frequency-specific first impedances and frequency-specific second impedances, and when the slope or the coefficient of determination of the linear graph deviates from a predefined criterion, determine that a connection failure exists. Various other examples of determining whether a connection failure exists are illustrated in FIGS. 6 to 14.

The present disclosure may also be embodied as computer-readable program code on a computer-readable recording medium. The computer-readable recording medium includes all types of recording devices storing data readable by a computer system. Examples of the computer-readable recording medium include read-only memory (ROM), random-access memory (RAM), compact disc ROM (CD-ROM), magnetic tape, floppy disk, and optical data storage device. In addition, the computer-readable recording medium may be distributed over network-connected computer systems such that computer-readable code is stored and executed in a distributed manner.

The present disclosure has been described with reference to preferred embodiments thereof. It will be understood by those of skill in the art that the present disclosure may be implemented in a modified form without departing from the essential characteristics of the present disclosure. Therefore, the disclosed embodiments are to be considered in a descriptive sense only, and not for purposes of limitation. The scope of the present disclosure is defined by the claims rather than the foregoing description, and all differences within the equivalent scope should be construed as being included in the present disclosure.

1. A method of identifying a connection failure in a battery module in which a plurality of cell modules are connected in series, the method comprising:
measuring a first impedance of the battery module;
calculating a second impedance by measuring impedances of the plurality of cell modules, respectively, and summing the measured impedances; and
determining whether a connection failure exists in the battery module, based on a difference between the first impedance and the second impedance.

2. The method of claim 1, wherein the measuring of the first impedance comprises
determining frequency-specific first impedances that are measured by inputting a plurality of different measurement frequencies to the battery module, and
the calculating of the second impedance comprises determining frequency-specific second impedances by summing impedances that are measured by inputting the plurality of different measurement frequencies to each of the plurality of cell modules.

3. The method of claim 2, wherein the determining of whether the connection failure exists comprises:
obtaining a linear graph by performing a regression analysis on values of differences between the frequency-specific first impedances and the frequency-specific second impedances; and
determining, based on a slope or a coefficient of determination of the linear graph deviating from a predefined criterion, that the connection failure exists.

4. A battery module diagnostic apparatus comprising:
a first measurement unit configured to determine a first impedance of a battery module in which a plurality of cell modules are connected in series;
second measurement unit configured to determine a second impedance by measuring impedances of the plurality of cell modules, respectively, and summing the measured impedances; and
a diagnosis unit configured to determine whether a connection failure exists in the battery module, based on a difference between the first impedance and the second impedance.

5. The battery module diagnostic apparatus of claim 4, wherein the first measurement unit is further configured to determine frequency-specific first impedances that are measured by inputting a plurality of different measurement frequencies to the battery module, and
the second measurement unit is further configured to determine frequency-specific second impedances by summing impedances that are measured by inputting the plurality of different measurement frequencies to each of the plurality of cell modules.

6. The battery module diagnostic apparatus of claim 5, wherein the diagnosis unit is further configured to obtain a linear graph by performing a regression analysis on values of differences between the frequency-specific first impedances and the frequency-specific second impedances, and determine, based on a slope or a coefficient of determination of the linear graph deviating from a predefined criterion, that the connection failure exists.

7. A computer-readable recording medium having recorded thereon a program for performing the method of claim 1.
